(19) United States
(12) Patent Application Publication
(10) Pub. No.: US 2006/0157786 A1
(43) Pub. Date: Jul. 20, 2006

(54) Semiconductor device and manufacturing method thereof

(75) Inventor: Hiroki Matsumoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/322,304

(22) Filed: Jan. 3, 2006

(30) Foreign Application Priority Data
Jan. 11, 2005 (JP) 3786/2005

(51) Int. Cl. H01L 27/12; H01L 21/84

(52) U.S. Cl. 257/347; 438/149; 257/E27.112; 257/E23.137

(57) ABSTRACT

A semiconductor device of the present invention includes: an SOI substrate that is a semiconductor wafer on which a semiconductor active layer is formed via a laminated insulating film; an insulating film which is arranged in a device isolation region surrounding an element forming region of the SOI substrate, and on the semiconductor active layer, and has a plurality of network shaped openings; and an gettering region arranged in the semiconductor active layer adjacent to the openings.

### BACKGROUND OF THE INVENTION

1. Field of the Invention

The present invention relates to a semiconductor device using an SOI substrate and manufacturing method thereof, more particularly, relates to a semiconductor device having a gettering region which gets pollutants such as heavy metals, and manufacturing method thereof.

2. Description of the Related Art

A semiconductor device using an SOI (Silicon On Insulator) substrate that is a semiconductor wafer on which a semiconductor active layer is formed via a laminated insulating film is considered to be applied to low power consumption LSIs, because it operates at high speed even if using a low voltage power supply. In a semiconductor device using such an SOI substrate, the thickness of the semiconductor active layer is thin, for example; 10 micron order, the entire region of the semiconductor active layer is defect free, and there is a laminated insulating film below the semiconductor active layer. In such configuration, since pollutants in a manufacturing process such as heavy metals, is not gotten (absorbed; gettering) with the semiconductor active layer, and the laminated insulating film prevents the pollutants from passing through, the rear surface of the substrate (the rear surface of a semiconductor wafer in the SOI substrate) cannot be used as a gettering site (crystal defect, strained layer, stress field) like a common wafer. Thus, pollutants will be remained in the semiconductor active layer on the laminated oxide film, thereby, occurring leakage current in an element formed on the SOI substrate, deteriorating the film quality of gate oxide film, or the like may affect the device formed on the SOI substrate. In particular, the element formed on the SOI substrate has less Qbd (Charge to breakdown) of the gate oxide film than that of an element formed on a usual wafer. Therefore, in the semiconductor device using an SOI substrate, it is required to effectively get pollutants, and to improve the reliability of the element. From such requirement, a semiconductor device using an SOI substrate, in which gettering region is formed in the device isolation region, is disclosed (see; Japanese Patent Laid-open No. H11-297703).

In the semiconductor device described in Japanese Patent Laid-open No. H11-297703, a gettering region is formed as follows. First, an SOI substrate 101 that is a semiconductor wafer 101a on which a semiconductor active layer 101c (p-type or n-type) is formed via a laminated insulating film 101b is provided. The semiconductor active layer 101c is divided into islands by an isolation trench 112 reaching to the laminated insulation film 101b, and the isolation trench 112 is buried with poly-silicon via oxide film (see; FIG. 3A). Next, oxide film 102 is formed on the SOI substrate 101, nitride film 103 is formed on the oxide film 102, a photoresist 104 is coated on the nitride film 103, and the nitride film 103 on a device isolation region 113 and the photoresist 104 are removed through patterning and etching (see; FIG. 3B). After then, ion implantation is performed in the device isolation region 113 below the oxide film 102 by ionizing oxide atom or Si atom using the photoresist 104 and the nitride film 103 as masks (see; FIG. 3C). Subsequently, after removing the photoresist 104, a LOCOS (Local Oxidation of Silicon) oxide film 109 is formed in the device isolation region 113 by thermal oxidation process to remove the nitride film 103 and oxide film 102 (see; FIG. 3D). If the ion implanted material is oxygen atom, a region of the device isolation region 113 in which a part of the oxygen atoms deposited by thermal oxidation process or the subsequent heat treatment becomes a gettering region 108 (gettering site). If the ion implanted material is Si atom, in the course of crystallization due to heat treatment, a local stress occurred by Si atom to form crystal defects, and a region in which the crystal defects are formed, becomes the gettering region 108 (gettering site). In this manner, gettering of pollutants such as heavy metals, which is introduced during forming a semiconductor device, can be done by the gettering region 108 formed below the LOCOS oxide film 109 of the device isolation region 113.

However, since the manufacturing method of a semiconductor device, which is described in Japanese Patent Laid-open No. H11-297703, requires ion implantation step of oxide atom or Si atom in order to form a gettering region, the manufacturing method may be redundant.

### SUMMARY OF THE INVENTION

In the first aspect of the present invention, the semiconductor device is characterized by including: an SOI substrate that is a semiconductor wafer on which a semiconductor active layer is formed via a laminated insulating film; an insulating film that is arranged in a device isolation region surrounding the element forming region of the SOI substrate and on the semiconductor active layer, and has a plurality of network or line shaped openings; a gettering region that is arranged in the semiconductor active layer adjacent to the openings.

In the second aspect of the present invention, the semiconductor device is characterized by including: a semiconductor active layer; a LOCOS oxide film that is formed in a device isolation region being on the semiconductor active layer and defining the element forming region, and has a plurality of openings; and a gettering region that is formed in the semiconductor active layer below the LOCOS oxide film, corresponding to the openings.

In the third aspect of the present invention, the semiconductor device is characterized by including the steps of: forming silicon oxide film and silicon nitride film on an SOI substrate that is a semiconductor wafer on which a semiconductor active layer is formed via a laminated insulating film; forming a photoresist in network or line shape, on the silicon nitride film, over the entire surface of the element forming region of the SOI substrate and in the device isolation region; etching at least the silicon oxide film and the silicon nitride film, using the photoresist as a mask, until the semiconductor active layer is exposed; and after removing the photoresist, forming a LOCOS oxide film through thermal oxidation process using the silicon nitride film as a mask, the LOCOS oxide film having a plurality of network or line shaped openings for forming a gettering region in the device isolation region.

According to the present invention, it is possible to provide a highly reliable device that can effectively get pollutants such as heavy metals without newly adding a special step in a SOI, substrate.

### BRIEF DESCRIPTION OF THE DRAWINGS

FIGS. 1A, 1B are respectively a partially sectional view, and a partially plane view, schematically illustrating the configuration of the semiconductor device according to the first embodiment of the present invention;

FIGS. 2A to 2H are partially step sectional views schematically illustrating the manufacturing method of the semiconductor device according to the first embodiment of the present invention;

FIGS. 3A to 3D are partially step sectional views schematically illustrating the manufacturing method of the semiconductor device according to a related art example.

### DETAILED DESCRIPTION OF THE PREFERRED EMBODIMENTS

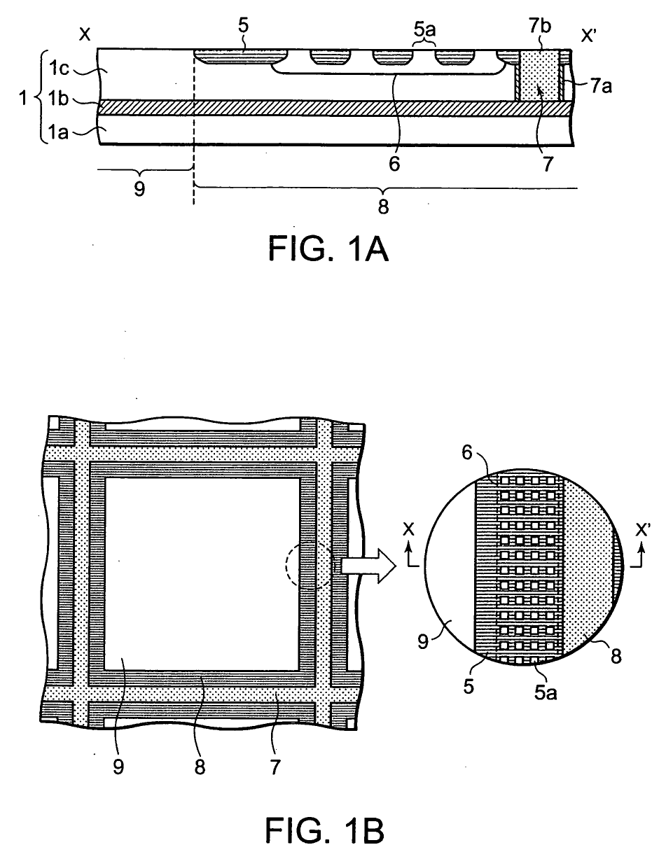

Now, referring to drawings, the semiconductor device according to the first embodiment of the present invention will be described. FIGS. 1 A, 1B are a partially sectional view and a partially plane view, schematically showing the configuration of the semiconductor device according to the first embodiment of the present invention, respectively.

The semiconductor device; a semiconductor device in which an SOI substrate 1 has a gettering region 6, includes an SOI substrate 1, a LOCOS oxide film 5, a gettering region 6, an isolation trench 7, a device isolation region 8, and an element forming region 9. For clarify, FIG. 1 shows an intermediate of the semiconductor device.

The SOI substrate 1 is a substrate that is a semiconductor wafer 1a on which a semiconductor active layer 1c is formed via a laminated insulating film 1b. The semiconductor active layer 1c is made from p-type or n-type silicon single crystal, and will be a p-type or an n-type well region in the future. The LOCOS oxide film 5 is silicon oxide film (insulating film) formed on the semiconductor active layer 1c by LOCOS process, and formed in the device isolation region 8. The LOCOS oxide film 5 is formed in mesh shape (net shape) viewed from plane direction and has a plurality of openings 5a formed in network shape (island shape). The gettering region 6, a region for getting pollutants such as heavy metals, is arranged in and near openings Sa of the LOCOS oxide film 5 of device isolation region 8 viewed from plane direction, is arranged in the semiconductor active layer 1c adjacent to the openings 5a viewed from plane direction, and also includes the semiconductor active layer 1c under the LOCOS oxide film 5 adjacent to the openings 5a. The isolation trench 7 is a trench for isolating the neighboring element forming regions, is formed in the semiconductor active layer 1c, and has a depth reaching to the insulating film 1b. The silicon oxide film 7a is formed on the inner wall surface of the isolation trench 7, in which a poly-silicon 7b is buried. The device isolation region 8, a region for isolating the neighboring element forming regions, is arranged around the element forming region 9 of the region surrounded by the isolation trench 7 viewed from plane direction, and includes the region to be openings 5a of the LOCOS oxide film 5. The element forming region 9, a region for forming an element, is surrounded by the device isolation region 8 viewed from plane direction, and does not include the region to be openings 5a of the LOCOS oxide film 5.

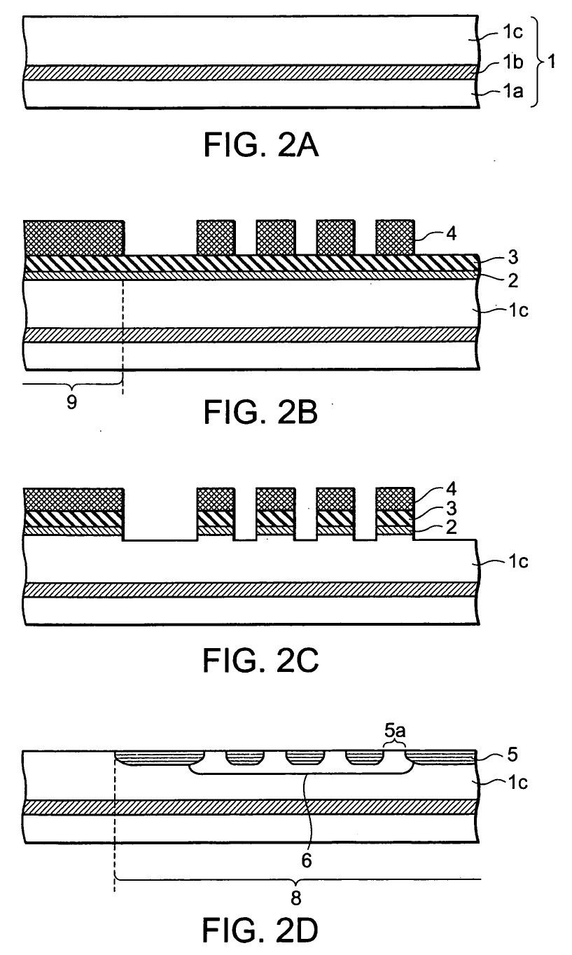

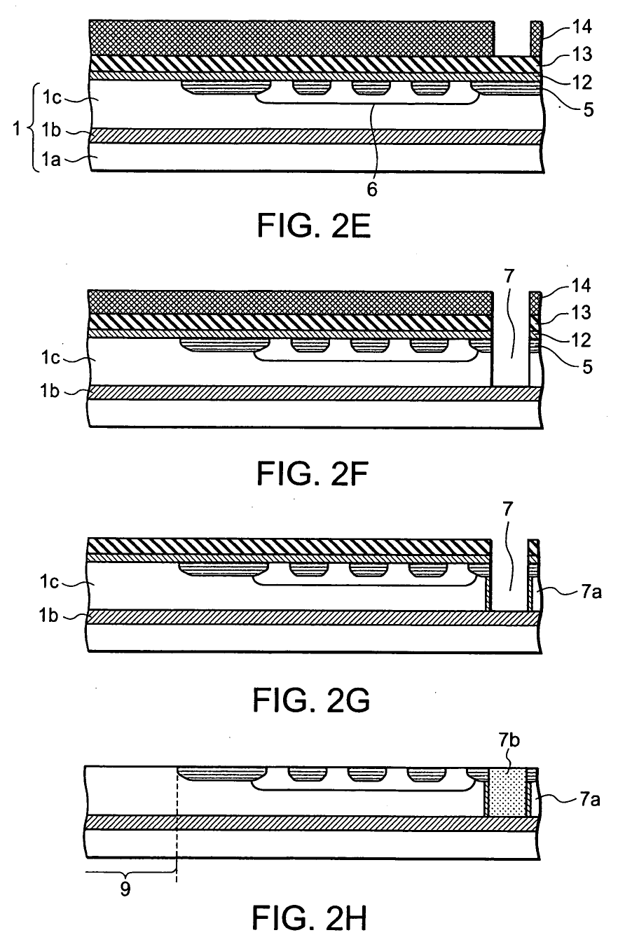

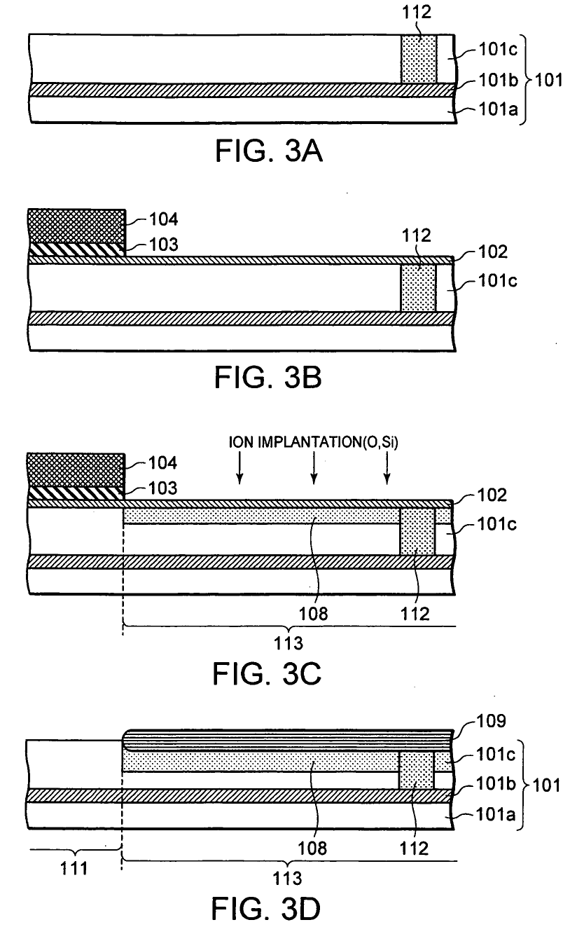

Next, referring to the drawings, the manufacturing method of a semiconductor device according to the first embodiment of the present invention will be described. FIGS. 2, 3 are partially step sectional views schematically showing the manufacturing method of the semiconductor device according to the first embodiment of the present invention.

First, an SOI substrate 1 that is a semiconductor wafer 1a on which a semiconductor active layer 1c is formed via a laminated insulating film 1b is provided (see; FIG. 2A).

Next, silicon oxide film 2 is formed on the semiconductor active layer 1c, silicon nitride film 3 is formed on the silicon oxide film 2, a photoresist 4 is coated on the silicon nitride film 3, and the photoresist 4 is patterned in a predetermined shape using photolithography process (see; FIG. 2B). Here, the photoresist 4 is formed on a region to be an element forming region 9 and openings (5a in FIG. 2D) of the LOCOS oxide film in the future.

Next, using the photoresist 4 as an etching mask, the silicon nitride film 3 and the silicon oxide film 2 (and a part of the semiconductor active layer 1c) are removed until the semiconductor active layer 1c is exposed by dry etching process (see; FIG. 2C). It is preferred to remove a part of the semiconductor active layer 1c, estimated amount of rising of the LOCOS oxide film, in order to construct planar LOCOS structure in which the surface of the LOCOS oxide film (5 in FIG. 2D) and the surface of the semiconductor active layer 1c become a same level.

Next, after removing the photoresist (4 in FIG. 2C), using the silicon nitride film 3 as a mask, a LOCOS oxide film 5 is formed in the device isolation region 8 by thermal oxidation process, after then, the oxide film (not shown) on the silicon nitride film 3 formed by thermal oxidation process, the silicon nitride film (3 in FIG. 2C), and the silicon oxide film (2 in FIG. 2C) are removed (see; FIG. 2D). Thereby, a LOCOS oxide film 5 having a plurality of openings 5a is formed, and a gettering region 6 is formed in the semiconductor active layer 1c adjacent to the openings 5a.

Next, silicon oxide film 12 is formed on the semiconductor active layer 1c and the LOCOS oxide film 5, silicon nitride film 13 is formed on the silicon oxide film 12, a photoresist 14 is coated on the silicon nitride film 13, and the photoresist 14 is patterned in a predetermined shape (see; FIG. 2E). Here, the photoresist 14 is formed on the LOCOS oxide film 5 except the region to be the isolation trench (7 in FIG. 2F) in the future in a shape divided into a network (islands).

Next, using the photoresist 14 as an etching mask, the silicon nitride film 13, the silicon oxide film 12, the LOCOS oxide film 5, and the semiconductor active layer 1c are removed until the laminated insulating film 1b is exposed, by dry etching process (see; FIG. 2F). Here, an isolation trench 7 is formed by removing the LOCOS oxide film 5 and the semiconductor active layer 1c.

Next, after removing the photoresist 4, silicon oxide film 7a is formed on the inner wall surface of the trench isolation 7 (see; FIG. 2G) by thermal oxidation process.

Next, after burying poly-silicon 7b in the isolation trench (7 in FIG. 2 G; silicon oxide film 7a) by CVD process, using silicon nitride film (13 in FIG. 2G) as a stopper, the trench is flattened by CMP process to remove the silicon nitride film (13 in FIG. 2G) and silicon oxide film (12 in FIG. 2G) (see; FIG. 2H). After then, an element will be formed in the element forming region 9, and further, wirings will be formed (not shown). Here, the unnecessary polysilicon 7b is removed by CMP process, however, the unnecessary polysilicon 7b may be removed by etch back method using dry etching process.

When the semiconductor device in the state of FIG. 2D is viewed from plane direction, a LOCOS oxide film 5 formed in the device isolation region 8, has a large number of openings 5a on the SOI substrate 1 in network shape (island shape) A large number of concaves are formed on the SOI substrate 1 (on the semiconductor active layer Ic) in mesh shape (net shape), and thermally oxidized. Due to stress accompanied by the thermal oxidation process of the semiconductor active layer 1c (silicon), strain occurs in the Si crystal lattice in the semiconductor active layer 1c adjacent to the interface between the semiconductor active layer 1c and the LOCOS oxide film 5. Especially, since there are a large number of openings 5a in the LOCOS oxide film 5 on an SOI substrate 1, the strain of crystal lattice becomes larger adjacent to the center of each opening 5a (viewed from plane direction), thereby a large number of crystal defects are generated in the gettering region 6 in the semiconductor active layer 1c. Due to the crystal defects, pollutants composed of heavy metals can be absorbed. The formation of the gettering region 6 does not add manufacturing processes, because it does not require an ion implantation step.

### Second Embodiment

In the second embodiment of the present invention, the shape of openings 5a of a LOCOS oxide film 5 may be L-shape, T-shape, cross-shape, arbitral polygon-shape, or line-shape.

What is claimed is:

1. A semiconductor device comprising:
an SOI substrate;
an insulating film arranged in a device isolation region surrounding an element forming region of said SOI substrate, and on a semiconductor active layer of said SOI substrate, said insulating film having a plurality of network or line shaped openings; and
a gettering region arranged in said semiconductor active layer adjacent to said openings.

2. The semiconductor device claimed in claim 1, further comprising an isolation trench dividing into islands said semiconductor active layer per each said element forming region, and penetrating said insulating film and said semiconductor active layer in said device isolation region to reach to said laminated insulating film.

3. The semiconductor device claimed in claim 1, wherein said insulating film having openings is a LOCOS oxide film.

4. A semiconductor device comprising:
a semiconductor active layer;
a LOCOS oxide film formed in a device isolation region being on said semiconductor active layer and defining the element forming region, and having a plurality of openings; and
a gettering region formed in said semiconductor active layer below said LOCOS oxide film, corresponding to said openings.

5. A manufacturing method of a semiconductor device comprising:
forming silicon oxide film and silicon nitride film on an SOI substrate;
forming a photoresist in network or line shape, on said silicon nitride film, over the entire surface of the element forming region of said SOI substrate and in the device isolation region;
etching at least said silicon oxide film and said silicon nitride film, using said photoresist as a etching mask, until said semiconductor active layer is exposed; and
after removing said photoresist, forming a LOCOS oxide film through thermal oxidation process using said silicon nitride film as a mask, said LOCOS oxide film having a plurality of network or line shaped openings for forming a gettering region in said device isolation region.

6. The manufacturing method of the semiconductor device claimed in claim 5, further comprising forming an isolation trench that divides into islands said semiconductor active layer per each said element forming region, and penetrates said LOCOS oxide film and said semiconductor active layer in said device isolation region to reach to said laminated insulating film.
